(19) United States
(12) Patent Application Publication
(10) Pub. No.: US 2013/0180446 A1
(43) Pub. Date: Jul. 18, 2013

(54) SUSCEPTOR

(71) Applicants: Yu Jin KANG, Basan (KR); Young Su KU, Gumi-si (KR); Suk June KANG, Chilgok-gun (KR)

(72) Inventors: Yu Jin KANG, Basan (KR); Young Su KU, Gumi-si (KR); Suk June KANG, Chilgok-gun (KR)

(21) Appl. No.: 13/740,779

(22) Filed: Jan. 14, 2013

(30) Foreign Application Priority Data
Jan. 13, 2012 (KR) 10-2012-0004219

(51) Int. Cl. H01L 21/683

(52) U.S. Cl. CPC H01L 21/683
USPC 117/84; 118/728; 134/22.1

(57) ABSTRACT

A susceptor includes a plurality of holes in a first area and a plurality of holes in a second area. The first and second areas overlap a location which corresponds to at least one portion of a semiconductor device to be processed. The holes in the first area are provided in a first pattern and the holes in the second area are provided in a second pattern which may be different from the second pattern. The first and second patterns may differ, for example, based on the size, arrangement, spacing, location, and/or density of the holes.

### CROSS-REFERENCE TO RELATED APPLICATIONS

The present application claims the benefit of priority under 35 U.S.C. 119 to Korean Patent Application No. 10-2012-0004219 filed on Jan. 13, 2012 which is hereby incorporated by reference in its entirety.

### BACKGROUND

Semiconductor wafers are formed using various techniques. One technique involves cutting a cylindrical ingot, grown using a Czochralski method, into thin disk shapes with a cutter and then chemically and mechanically grinding the surfaces thereof.

A process of forming a high purity crystalline layer with crystal orientations aligned on a surface of a single crystalline silicon wafer grown using the Czochralski method is referred to as an epitaxial growth method or, more simply, an epitaxial method. A layer formed using this method is called an epitaxial layer or an epi-layer, and a wafer including an epi-layer is called an epitaxial wafer. One type of epitaxial method is performed by a reactor which operates under high temperature conditions and which includes a susceptor on which a wafer is placed to grow an epi-layer.

Epitaxial methods have proven to have drawbacks. For example, n-type or p-type ions may migrate between a susceptor and an upper surface of a polished wafer. As a result, the edge of the wafer may be doped with ions to an undesirably high concentration. This is called auto-doping. Another drawback relates to the inability of a cleaning gas to completely remove a natural oxide layer from a wafer. As a result, reaction gas may be deposited on a rear surface of the wafer during epitaxial deposition, which is called haloing.

Auto-doping and haloing significantly degrade wafer quality and the corresponding semiconductor chip made from the wafer.

Another drawback relates to the heat generated from a heating source during chip fabrication. This heat places thermal stress on the wafer, which, in turn, may cause slip dislocation and increase surface roughness of a rear surface of the wafer, both of which may degrade the nano-quality of the wafer. In addition, a heavily and thermally stressed region may cause a defect to occur in a device process.

Another drawback of susceptors relates to wear during use. More specifically, because the wafer is placed on a susceptor during a heating process, the susceptor may be worn by friction. Even though a small portion of a silicon carbide coating layer formed on the susceptor may be damaged by the friction, the susceptor should be replaced with a new one. Otherwise, material such as graphite removed from the susceptor may cause an epitaxial reactor to malfunction. This increases operation costs of the epitaxial reactor.

### SUMMARY

In one embodiment, a susceptor includes: a recess part in which a wafer is placed, wherein the recess part aligned with the wafer includes: a first region having first type holes passing through the recess part in at least one portion of a region ranging from about 92% to about 98% of a radius of the wafer from a center of the recess part; a second region disposed at an inside of the first region, and having second type holes that pass through the recess part and are different from the first type holes; and a third region disposed at an outside of the first region and having no hole, wherein the first type holes are spaced apart from each other, and an imaginary line connecting the first type holes is substantially circular.

In another embodiment, a susceptor includes: a recess part in which a wafer is placed, wherein the recess part includes: a first region having first type holes passing through the recess part; a second region disposed at an inside of the first region, and having second type holes that pass through the recess part and are greater than the first type holes; and a third region disposed at an outside of the first region and having no hole, the first region is smaller than the second region in terms of width along a radial direction of the wafer.

In another embodiment, a susceptor includes: a recess part aligned with a wafer in an up-and-down direction, wherein the recess part includes: a first region having first type holes passing through the recess part; a second region disposed at an inside of the first region, and having second type holes that pass through the recess part and are different from the first type holes; and a third region disposed at an outside of the first region and having no hole, the first type hole having a diameter from about 7.2 mm to about 8.8 mm.

### BRIEF DESCRIPTION OF THE DRAWINGS

FIG. 1 shows one embodiment of an epitaxial reactor.

FIG. 2 shows a susceptor of the reactor of FIG. 1.

FIG. 3 shows another view of the susceptor.

FIG. 4 shows another view of the susceptor.

FIG. 5 shows experimental and comparative examples.

FIG. 6 shows a method for making a semiconductor device.

### DETAILED DESCRIPTION

FIG. 1 shows one embodiment of an epitaxial reactor that includes lift pins 1, a lift pin support shaft 2, and a blade 5. The blande loads and unloads a wafer 6 to and from a reactor. When the blade 5 is taken out, the lift pin support shaft 2 pushes up the lift pins 1 to support the wafer 6 from a lower side thereof. The pins may be spaced apart from each other to provide improved support.

When the reactor is operated, the wafer 6 is placed on a susceptor 3 and the wafer is heated by or through the susceptor. A susceptor supporting shaft 4 moves the susceptor in upward and downward directions and supports the susceptor 3 from a lower side thereof. Once the blade 5 is removed, the lift pins 1 are moved downward and the susceptor 3 supported by the susceptor supporting shaft 4 is moved upward such that the wafer 6 is placed on the susceptor 3. Thereafter, a series of processes including a susceptor heating process and a gas supplying process are performed to grow a single crystalline layer.

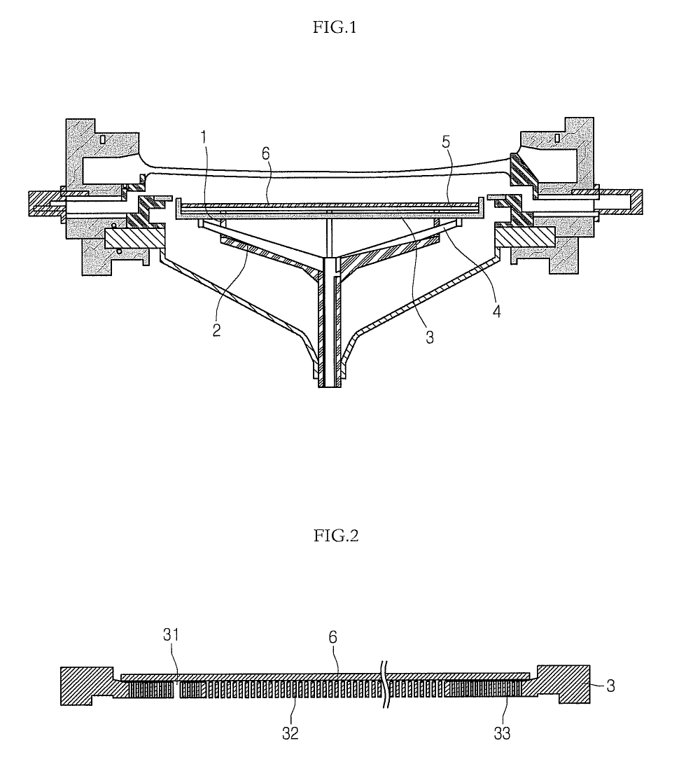

FIG. 2 shows a relative position between the wafer and the susceptor. As shown, the susceptor 3 may be include a pocket or recess at an inner portion which extends in a downward direction and the wafer 6 may be placed in the recess. The wafer 6 may be placed on a top surface of the susceptor 3, and the susceptor may include lift pin holes 31 to allow vertical movement of the lift pins 1.

In addition to these features, the susceptor 3 includes holes 32 and 33 to allow for movement of gas to a lower side thereof. The holes 32 and 33 are classified into second-type holes (denoted by 32) disposed in an inner portion of the susceptor 3 and first-type holes (denoted by 33) disposed in an outer portion of the susceptor. The holes 32 and 33 may have a circular shape or another shape including but not limited to a polygonal shape. Because the second-type holes 32 are disposed in the inner portion of the susceptor 3, the second-type holes 32 affect the inner portion of a wafer. Since the first-type holes 33 are disposed in the outer portion of the susceptor 3, the first-type holes 33 affect the edge of a wafer. The second type holes 32 and the first type holes 33 will now be described in detail.

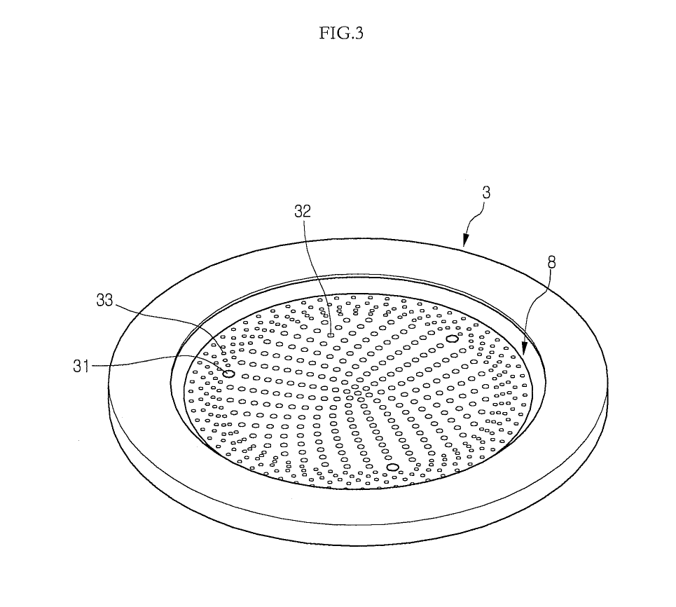

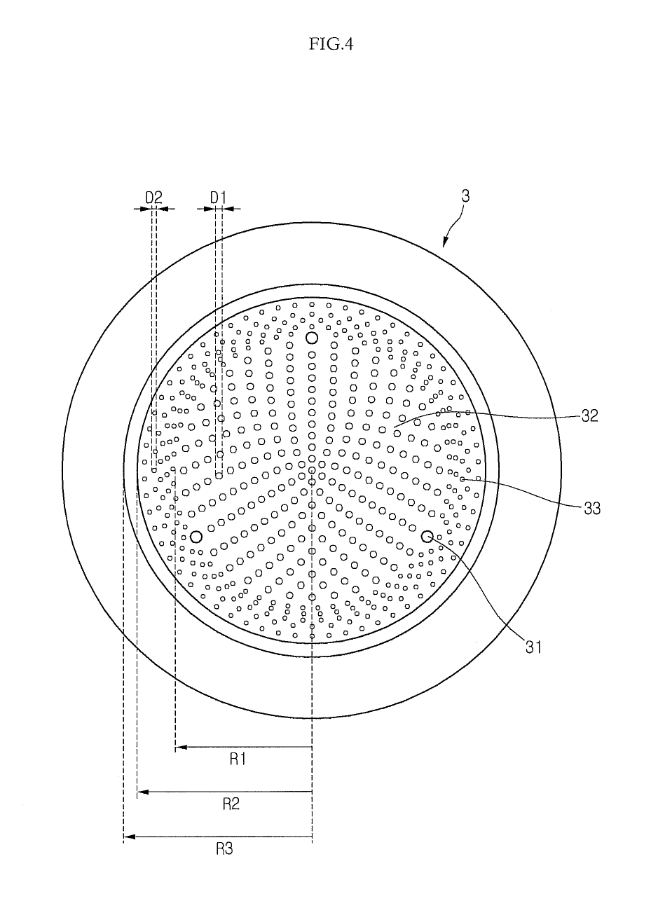

FIG. 3 shows another view of the susceptor. As shown, a wafer on which a layer is grown is placed on the susceptor 3. The susceptor 3 includes a recess part 8 which extends in a downward direction to accommodate a wafer. The second-type holes 32 are disposed in the inner portion of the recess part 8 and the first-type holes 33 are disposed in the outer portion thereof. (For clarity, a region of the recess part 8 in which the second-type holes 32 are disposed may be referred to as a second region, and a region of the recess part 8 in which the first-type holes 33 are disposed may be referred to as a first region).

In at least some embodiments, the second type-holes 32 and the first-type holes 33 may serve to improve flow efficiency of a processing gas (e.g., cleaning gas, discharge gas, etc.) and/or may prevent heat from a heat source from directly affecting the edge of a wafer. Accordingly, auto-doping and haloing can be reduced or altogether suppressed and edge stress can be decreased.

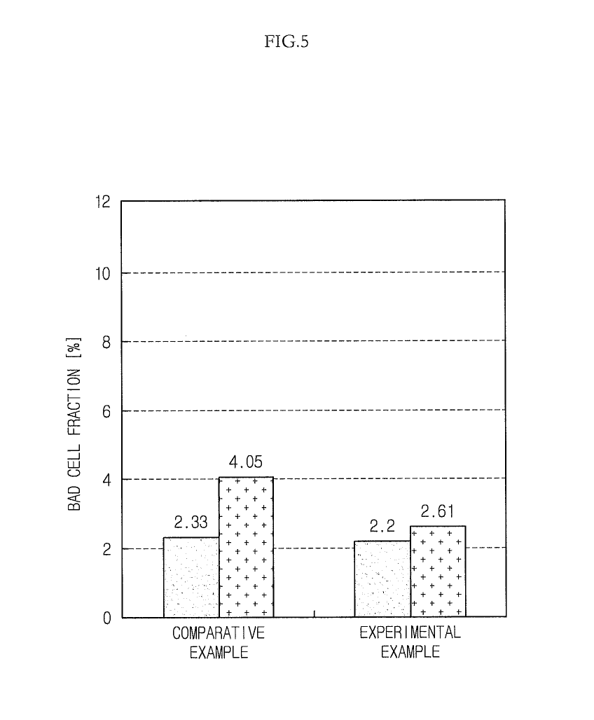

FIG. 4 shows another view of the susceptor in FIG. 1 showing possible shapes and arrangements of the second-type holes 32 and the first type holes 33. As shown, the second-type holes 32 are arrayed at predetermined intervals in the susceptor 3. As a result, various types of gas can be efficiently discharged from between the wafer 6 and the inner portion of the susceptor 3 or be efficiently dispersed therebetween.

The first-type holes 33 are disposed outside of the second-type holes 32, and therefore gas can be discharged from the outer portion of the susceptor 3. In accordance with one embodiment, the first-type holes 33 may be disposed at an outer portion of the susceptor 3 in a region ranging from a radius R1 to a radius R2. According to one example, the radius R2 may be about 98% of the entire radius of the wafer 6 relative to a center of the susceptor 3, and the radius R1 may be about 92% of the entire radius of the wafer 6 from the center of the susceptor 3. The values of R1 and R2 may be different in other embodiments. Also, in this example, no holes may exist in a third region which lies outside the region containing the first-type holes 33.

The first-type holes 33 may be arrayed in a circular pattern at one or more radial distances that correspond to approximate circular lines in the outer portion of the susceptor 3. For example, a first imaginary circular line may pass through a first plurality of first-type holes 33 located at a first radial distance from the center, and a second imaginary circular line may pass through a second plurality of first-type holes 33 located at a second radial distance from the center. Holes along additional circular lines may also be included.

In other embodiments, the first-type holes may be arranged in a pattern different from a circular pattern provided, for example, that the first-type holes 33 are disposed in the region ranging from the radius R1 to the radius R2. When the first-type holes 33 in the region ranging from radius R1 to radius R2 are arrayed along a plurality of hole lines that have different distances from the center of the susceptor 3, stress (e.g., thermal stress) applied to the edge of the wafer 6 may be controlled more effectively.

As shown in FIG. 4, the first-type holes 33 are spaced inwardly from a boundary of the wafer 6 by a predetermined amount (for example, in a range of about 2% to 8% of the radius of wafer 6). This allows the first-type holes 33 to overlap the wafer (e.g., prevents any of the holes from being located at a position which extends in a non-overlapping relationship relative to the wafer), and this is so even though the wafer might not be exactly aligned within the recess of the susceptor 3.

More specifically, at least a region ranging from radius R2 to radius R3 as shown in FIG. 4 may be provided for. In addition, the region ranging from radius R2 to R3 prevents heat from a heat source from being directly emitted to the outermost portion of the wafer 6, thereby reducing or suppressing thermal stress.

The first-type holes 33 may improve flow efficiency of a processing gas as previously described. According to an example, when an epitaxial layer is grown on a wafer having a diameter of 300 mm, the first-type holes 33 may be disposed in a range from about 138 mm to about 148 mm from the center of the susceptor 3.

The second-type holes 32 are disposed at the inside of the first-type holes 33 (e.g., a region within radius R1) to improve the flow efficiency of a processing gas in the inner portion of the susceptor 3. The second-type holes 32 may have a diameter different from that of the first-type holes 33. According to one example, the second-type holes 32 may have a diameter D1 ranging from about 0.9 mm to about 1 mm. In other embodiments, the holes 32 and 33 may have different relative sizes or may be equal in size.

If the second-type holes 32 have an excessively large diameter, heat from the heat source may directly and adversely affect the wafer. Conversely, if the second-type holes 32 have an excessively small diameter, the ability to form the holes may prove to be difficult and the coating efficiency in holes may be deceased, which, in turn, may decrease the service life of a susceptor and/or increase the likelihood of producing defective wafers.

According to one example, the first-type holes 33 have a diameter that is about 55 to 88% of the diameter of the second-type holes 32. Because the first-type holes 33 are smaller than the second-type holes 32 in this example, damage of the wafer 6 due to heat from a heat source is decreased, thereby further decreasing thermal stress concentrated at the edge of the wafer 6.

In determining hole size, there may be some countervailing considerations. For example, if the first-type holes 33 have an excessively small diameter, hole forming efficiency, gas flow efficiency, and coating efficiency may be degraded. And, if the first-type holes 33 have an excessively large diameter, thermal stress applied to the wafer from a heat source may not be adequately reduced or suppressed. Accordingly, in one non-limiting example, the first-type holes 33 may have a diameter D2 ranging from about 7.2 mm to about 8.8 mm.

The distances and arrangements between the first-type holes 33 and second-type holes 32 may differ from embodiment to embodiment. For example, the distances between identical holes may be the same. In other embodiments, however, these distances may be different. Also, the densities of identical holes may be uniform or different over the entire region of the susceptor 3.

In accordance with one or more embodiments, during operation, gas may enter the holes in various ways. For example, the wafer may be thin and not perfectly flat. In this case, undulations in the wafer may create spaces which may allow processing gases (e.g., discharge gas, cleaning gas, etc.) to flow under the wafer to enter the holes.

Additionally, or alternatively, heat from a heat source may cause the wafer to temporarily deform to thereby create spaces for allowing gas to enter the underlying holes.

Additionally, or alternatively, the susceptor may be partially or wholly curved. This will allow spaces to formed between the bottom surface of the wafer and the susceptor, which spaces will allow gas to enter the holes of the second body.

Additionally, or alternatively, the width of the wafer may not be co-extensive with the width of the susceptor. As a result, holes along the peripheral edge may be left uncovered by the wafer, thereby allowing gas to enter the holes.

Auto-doping or other non-uniformity effects may be controlled, for example, as a result of ions or dopants passing through the holes to prevent, for example, an over concentration of doping at any one region of the wafer.

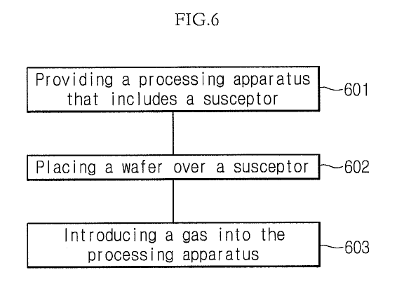

FIG. 5 is a graph showing experimental and comparative examples. In forming this graph, two experiments were performed using different silicon ingot manufacturing processes and two experiments using different susceptors were performed.

In the comparative example, first-type holes were disposed in a region between about 92% to 85% of the radius of a wafer, and the first-type holes and second-type holes had a same diameter of about 1.00 mm. In the experimental example, the first-type holes were disposed in a region corresponding to about 93% of the radius of a wafer, and the first-type holes had a diameter of about 0.89 mm and second-type holes had a diameter of about 1.00 mm. Table 1 shows conditions of the experiments.

TABLE 1

| | Comparative | Comparative | Experimental | Experimental |
|---|---|---|---|---|
| | Example 1 | Example 2 | Example 1 | Example 2 |
| Ingot | A | B | A | B |
| Manufacturing | | | | |
| Process | | | | |
| Outermost | 85% | 85% | 93% | 93% |
| Position of | | | | |
| First Type | | | | |
| Holes | | | | |
| (First Type | | | | |
| Hole | | | | |
| Position/Wafer | | | | |
| Radius) | | | | |
| Diameter of | 1.00 mm | 1.00 mm | 0.89 mm | 0.89 mm |
| First Type Hole | | | | |
| Diameter of | 1.00 mm | 1.00 mm | 1.00 mm | 1.00 mm |
| Second Type | | | | |
| Hole | | | | |

According to results of the experiments, a bad cell fraction (%) of devices formed from a wafer was decreased in the experimental examples, and thus the yield rate of devices was increased. As a result, auto-doping, haloing, and thermal edge stress was reduced substantially, to thereby improve efficiency of a device process. More specifically, the comparative examples demonstrated a bad cell fraction of 2.33% and a bad cell fraction of 4.05%, respectively, and the experimental examples demonstrated a bad cell fraction of 2.2% and a bad cell fraction of 2.61%, respectively.

FIG. 6 shows operations included in a method for making at least a portion of a semiconductor device, where the portion may include a wafer or substrate for use in the device. The device may include a processor, memory, bus structure, light emitter, or any device that can be manufactured using semiconductor technology.

The method includes providing a processing apparatus that includes a susceptor. (Block 601). The processing apparatus may be a processing chamber which introduces a discharge gas proximate the wafer for purposes of preparing the wafer for further semiconductor processing. Additionally, or alternatively, the chamber may introduce a cleaning gas for purposes of cleaning the wafer before or after discharge and/or another type of processing operation is performed.

A second operation includes placing a wafer over the susceptor. (Block 602). This may be accomplished, for example, by a robot arm or blade placing the wafer over and/or onto the susceptor. For example, as shown in FIG. 2 the blade may place the wafer into a recess of the susceptor at a location over the holes.

A third operation includes introducing a gas into a location of the chamber that includes the wafer and susceptor. (Block 603). The gas may be, for example, any of the gases previously mentioned or another gas, and the susceptor may have a configuration in accordance with any of the embodiments described herein.

In some of the figures, the recess part is shown to have slanted or vertical walls. If slanted, the slope of the slant may be steep or gradual. In alternative embodiments, the walls of the recess part may have a stepped structure. In addition, although the lift pins are disposed in a region corresponding to the second-type holes, in alternative embodiments the lift pins may be disposed in a region corresponding to the first-type holes. The position of the lift pins may be determined, for example, based on the reactor type and/or structure.

In addition, the size, position, and arrangement of the holes according to the foregoing embodiments may be varied or selectively combined to form new embodiments. For example, holes in the outer portion of the susceptor may be smaller than holes in the inner portion thereof. Also, the positions of the holes may differ from those shown in the foregoing embodiments. For example, the first-type and second-type holes may be disposed in an alternating pattern either within a same row (e.g., circular line) or rows containing the first- and second-type rows may be alternated.

In the figures, the holes are arranged in a pattern that follows the same general shape of the edge of the wafer, e.g., the holes are arranged along circular paths at different radial distances from the center and the outer edge of the wafer is also circular. In other embodiments, the shape of the wafer edge and the hole pattern(s) may be different.

In addition, at least one of the density, shape, or inclination of the first- and second-type holes passing through the susceptor may be the same or different. Variations in the inclination angle may be controlled to attain an effect which corresponds to the effect attained by controlling the size and position of the second-type holes and first-type holes.

Although the two types of holes are exemplified in the above embodiment, in other embodiments three or more types of holes may be exemplified having different sizes, shapes, densities, inclination angles, pattern of arrangement and/or radial distances from the center of the susceptor.

Also, although the first-type holes and the second-type holes are shown in some figures to have a circular pattern, the first-type holes and/or second-type holes may be arranged in a polygonal, random, or other pattern.

In accordance with at least one embodiment, the recess part may have slanted or stepped walls and a peripheral edge of the wafer may contact the slanted or stepped walls so that the wafer is located within the susceptor at a position below an upper surface of the susceptor. When located in this manner, a gap may be formed between the first- and second-type holes and a bottom surface of the wafer to allow for gas to exit the holes and/or heat to pass through the holes during processing.

Alternatively, the wafer may rest directly on top of the holes even through the recess part has slanted or stepped walls. This same alternative may be achieved, for example, when the walls of the recess part extend in substantially a vertical direction as in FIG. 2.

In accordance with one or more embodiments, the adverse effects of auto-doping, haloing, and/or damage due to thermal stress can be reduced or suppressed.

In addition, the quality of a semiconductor device may be ensured and the yield rate of semiconductor devices can be increased. Particularly, thermal stress applied to the edge of a wafer can be decreased so as to increase the yield rate of devices. Accordingly, semiconductor chips may be formed to have competitive pricing. Also, presently, wafers having a diameter of 300 mm are in widespread use. However, as wafer diameter increases or otherwise changes, one or more embodiments described herein may reduce or suppress the possibility of auto-doping, haloing, and/or edge stress, making the embodiments desirable from an industry standpoint.

In accordance with one embodiment, a susceptor comprises a plurality of first holes in a first area and a plurality of second holes in a second area, wherein: the first holes are provided in a first pattern, the second holes are provided in a second pattern, the first pattern is different from the second pattern, and the first and second areas overlap a location which corresponds to at least one portion of a semiconductor device to be processed. The first holes and the second holes may be arranged substantially a same plane.

The first holes in the first pattern and the second holes in the second pattern may have different sizes, and/or the first holes in the first pattern and the second holes in the second pattern may be arranged to have different spacings.

The first area may be at a first distance from a center of the susceptor, the second area may be at a second distance from the center of the susceptor. The first distance may be different from the second distance, and in one embodiment the first distance may be greater than the second distance. Also, the first pattern may be different from the second pattern. The first pattern and the second pattern may be substantially circular patterns.

In addition, the susceptor may include a first surface above the first and second holes, a second surface which includes at least one of the first or second holes, and the second surface may lie in a first plane and the second surface lies in a second plane different from the first plane. Also,a third surface may be located between the first and second surfaces, and the third surface may be oriented in a direction different from the first and second surfaces.

In addition, at least a portion of the third surface may be located adjacent the location where the at least one portion of the semiconductor device is to be processed. The third surface may be slanted relative to at least one of the first or second surfaces, the third surface may be substantially perpendicular relative to at least one of the first or second surfaces, or the third surface may include at least one step. Also, at least a third hole may receive a lift pin, and the at least one portion of the semiconductor device is a wafer.

In accordance with another embodiment, a method of making at least a portion of a semiconductor device comprises: providing a processing apparatus that includes a susceptor; placing a wafer over the susceptor; and introducing a gas into a location of the processing apparatus that includes the wafer and susceptor, wherein the susceptor includes a plurality of first holes in a first area and a plurality of second holes in a second area. The first holes are provided in a first pattern, the second holes are provided in a second pattern, the first pattern is different from the second pattern, and the first and second areas overlap a location which corresponds to the at least one portion of the semiconductor device.

The at least one portion of the semiconductor device may include a wafer, the gas may be a discharge gas or a cleaning gas, and the first and second holes may be arranged substantially a same plane, and the first holes in the first pattern and the second holes in the second pattern may have different sizes or different spacings, or both.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments. The features of one embodiment may be combined with the features of one or more of the other embodiments.

Although embodiments have been described with reference to a number of illustrative embodiments, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A susceptor comprising:
a plurality of first holes in a first area; and
a plurality of second holes in a second area, wherein:
the first holes are provided in a first pattern,
the second holes are provided in a second pattern,
the first pattern is different from the second pattern, and
the first and second areas overlap a location which corresponds to at least one portion of a semiconductor device to be processed.

2. The susceptor of claim 1, wherein the first holes and second holes are arranged substantially a same plane.

3. The susceptor of claim 1, wherein the first holes in the first pattern and the second holes in the second pattern have different sizes.

4. The susceptor of claim 1, wherein the first holes in the first pattern and the second holes in the second pattern are arranged to have different spacings.

5. The susceptor of claim 1, wherein:
the first area is at a first distance from a center of the susceptor,
the second area is at a second distance from the center of the susceptor, and
the first distance is different from the second distance.

6. The susceptor of claim 5, wherein the first distance is greater than the second distance.

7. The susceptor of claim 1, wherein the first pattern is different from the second pattern.

8. The susceptor of claim 1, wherein the first pattern and the second pattern are substantially circular patterns.

9. The susceptor of claim 1, further comprising:
a first surface above the first and second holes,
a second surface which includes at least one of the first or second holes,
wherein the second surface lies in a first plane and the second surface lies in a second plane different from the first plane.

10. The susceptor of claim 10, further comprising:
a third surface between the first and second surfaces,
wherein the third surface is oriented in a direction different from the first and second surfaces.

11. The susceptor of claim 10, wherein at least a portion of the third surface is located adjacent the location where the at least one portion of the semiconductor device is to be processed.

12. The susceptor of claim 10, wherein the third surface is slanted relative to at least one of the first or second surfaces.

13. The susceptor of claim 10, wherein the third surface is substantially perpendicular relative to at least one of the first or second surfaces.

14. The susceptor of claim 10, wherein the third surface includes at least one step.

15. The susceptor of claim 1, further comprising:
at least a third hole to receive a lift pin.

16. The susceptor of claim 1, wherein the portion of the semiconductor device is a wafer.

17. A method of making at least a portion of a semiconductor device, comprising:
providing a processing apparatus that includes a susceptor;
placing a wafer over the susceptor; and
introducing a gas into a location of the processing apparatus that includes the wafer and susceptor, wherein the susceptor includes a plurality of first holes in a first area and a plurality of second holes in a second area, and wherein:
the first holes are provided in a first pattern,
the second holes are provided in a second pattern,
the first pattern is different from the second pattern, and
the first and second areas overlap a location which corresponds to the at least one portion of the semiconductor device.

18. The method of claim 17, wherein the at least one portion of the semiconductor device includes a wafer.

19. The method of claim 17, wherein the gas is a discharge gas or a cleaning gas.

20. The method of claim 17, wherein the first holes and second holes are arranged substantially a same plane, and the first holes in the first pattern and the second holes in the second pattern have different sizes or different spacings, or both.
